(19) United States
(12) Patent Application Publication
(10) Pub. No.: US 2026/0072065 A1
(43) Pub. Date: Mar. 12, 2026

(54) AIRBORNE SATELLITE ORBITAL SIMULATOR

(71) Applicant: QUADSAT APS, Odense N (DK)

(72) Inventors: Cosme CULOTTA-LOPEZ, Nordfyns (DK); Snorre STURLESON NORDAHL SKEIDSVOLL, Nordfyns (DK); Andrian BUCHI, Nordfyns (DK); Joakim ESPELAND, Nordfyns (DK); Milan Orlando HAASE, Nordfyns (DK); Ondrej POKORNY, Nordfyns (DK); Saki OMI, Nordfyns (DK)

(73) Assignee: QUADSAT APS, Odense N (DK)

(21) Appl. No.: 19/328,013

(22) Filed: Sep. 12, 2025

Related U.S. Application Data
(63) Continuation of application No. PCT/EP2024/056438, filed on Mar. 11, 2024.

(30) Foreign Application Priority Data
Mar. 13, 2023 (GB) 2303672.6

(51) Int. Cl. G01R 29/08

(52) U.S. Cl. CPC G01R 29/0878

(57) ABSTRACT

Here discloses an apparatus for evaluating the ground terminal antenna and simulating satellite orbital trajectory using at least one unmanned aerial vehicle configured to emulate satellite movement based on a pseudo satellite trajectory. Apparatus encompasses a base station for establishing telemetry with a ground terminal antenna and said at least one unmanned aerial vehicle on a flight path designed for a planned scenario of a satellite. The base station is configured to process the telemetry data and perform one or more measurements based on a set of operational angles and target direction of said at least one unmanned aerial vehicle on the flight in relation to providing the orbital trajectory simulation of the satellite with respect to the planned scenario. One or more measurements comprise an offset measurement based on the set of operational angles of the ground terminal antenna in relation to the target direction of said at least one unmanned aerial vehicle; and a tracking accuracy measurement based on the set of operational angles of the ground terminal antenna and target direction of said at least one unmanned aerial vehicle following the flight path for a time period.

### BACKGROUND

Present application relates to a system, apparatus, and method for evaluating satellite antennas and simulating the trajectory (and communication) of the satellite using one or more unmanned aerial vehicles (UAVs).

Antenna Under the Test (AUT) is a term coined for an antenna that is being evaluated. Measurements can be taken for the evaluation. These measurements may include but are not limited to, for example, offset (pointing) measurement and tracking accuracy measurement. Conventional ways of taking the measurements from the AUT exist.

In one way, the offset can be measured by conducting Sun/Moon tracking. During Sun/Moon tracking, the offset is evaluated by letting the AUT point toward the known astronomical object, typically the sun or the moon. However, measurements taken this way are often inaccurate and may not be fully utilized. Also, the process of taking the measurements tends to be lengthy and covers only specific areas where tracking objects are available.

Another way is through GEO satellite tracking. During GEO satellite tracking, the pointing offset is evaluated by letting the AUT point toward the known stationary satellite from the observer's points. LEO/MEO communication performance (e.g., drop rate, throughput, handover) can be evaluated by involving LEO/MEO satellites in operation at their orbits. However, satellite tracking is not a holistic approach to general testing. It lacks the needed flexibility, especially due to the limited number of deployable orbital satellites that are available and could be utilized for general testing.

Existing methods lack the accuracy or flexibility to holistically perform tests on the AUT. These methods also prevent further applications of AUT measurements. Thus, there is a need for a new satellite antenna measurement methodology using unmanned aerial vehicles (UAVs) to address and overcome the shortcomings of the existing methods.

The embodiments described below are not limited to implementations which solve any or all of the disadvantages of the known approaches described above.

### SUMMARY

This Summary is provided to introduce a selection of concepts in a simplified form that are further described below in the Detailed Description. This Summary is not intended to identify key features or essential features of the claimed subject matter, nor is it intended to be used to determine the scope of the claimed subject matter; variants and alternative features which facilitate the working of the invention and/or serve to achieve a substantially similar technical effect should be considered as falling into the scope of the invention disclosed herein.

The present disclosure provides an apparatus/system for evaluating ground antenna or AUT using unmanned aerial vehicle(s) or UAV(s) as pseudo satellite(s) under one or more planned/operational scenarios. The measurements taken with respect to the AUT may be applicable to the simulated trajectory (and communication) of the satellite in GEO/MEO/LEO/HEO or any other elliptical orbit, as well as operational scenarios, including LEOP (Launch and Early Operation), satellite deorbiting, satellite collision avoidance. The apparatus/system provides the capability to evaluate the pointing offset or tracking accuracy of the antenna on the ground (terminal antenna), offering flexibly customizable scenarios using UAV(s) with radio frequency (RF) payload.

More specifically, the present apparatus/system uses a single or multiple UAV(s) to emulate the pseudo satellite trajectory, constellation and RF signal to evaluate the pointing, tracking and handover functionality of ground terminal antenna (or otherwise referred to as antenna under the test) in any of the satcom scenario (e.g., GEO, NGSO, LEOP, environmental attenuation, doppler) by measuring data as required (e.g., signal strength, operational angle of AUT, throughput, throughput rate).

In a first aspect, the present disclosure provides an apparatus for evaluating the ground terminal antenna. The apparatus performs one or more measurements of ground terminal antenna using at least one unmanned aerial vehicle configured to emulate satellite movement and two-way signal communication based on a pseudo satellite trajectory, the apparatus comprising: a base station for establishing telemetry with a ground terminal antenna and said at least one unmanned aerial vehicle on a pre-determined or real-time guided flight path designed for a planned scenario of a satellite, the base station is configured to process the telemetry data and perform one or more measurements thereon, based on operational angle and target direction of said at least one unmanned aerial vehicle on the pre-determined or real-time guided flight, in relation to providing the orbital trajectory simulation of the satellite with respect to the planned scenario; and wherein said one or more measurements comprise 1) an offset measurement based on a set of operational angles of the ground terminal antenna in relation to the target direction of said at least one unmanned aerial vehicle; and 2) a tracking accuracy measurement based on the set of operational angles of the ground terminal antenna and target direction of said at least one unmanned aerial vehicle following the pre-determined flight path for a time period.

In a second aspect, the present disclosure provides an apparatus for simulating satellite orbital trajectory using a plurality of unmanned aerial vehicles, wherein the apparatus comprising: a base station controlled by a user interface to keep telemetry with the plurality of unmanned aerial vehicles and a ground terminal antenna, the base station is configured to monitor the plurality of unmanned aerial vehicles, record and analyze the data received from the plurality of unmanned aerial vehicles, and plan flight paths emulating satellite movement based on user input of one or more operational scenarios; and wherein the analysis comprises performing a set of measurements in relation to the data received during the telemetry.

In a third aspect, the present disclosure provides system, wherein the system comprising an apparatus configured according to the first aspect or the second aspect.

In a fourth aspect, the present disclosure provides a computer-implemented method of obtaining measurements taken with respect to one or more unmanned aerial vehicles, the method comprising: performing an offset measurement using data collected from said one or more unmanned aerial vehicles to determine the angular offset for a ground terminal antenna corresponding to the target direction of said one or more unmanned aerial vehicles, wherein the offset measurement is dependent on a set of operational angles of the ground terminal antenna; and performing a tracking accuracy measurement with respect to the ground terminal antenna using said one or more unmanned aerial vehicles based on the trajectory of each unmanned aerial vehicle projecting an orbital trajectory of a satellite, wherein tracking accuracy measurement evaluates whether the ground terminal antenna can track the target satellite with time.

In a fifth aspect is a method of providing a pseudo satellite dataset used for operating one or more unmanned aerial vehicles, the method comprising: designating an operational scenario; obtaining parameters associated with the operational scenario; generating the pseudo satellite dataset based on the operational scenario; generating a set of instructions associated with a state based on the pseudo satellite dataset; and sending the set of instructions for operating said one or more unmanned aerial vehicles in relation to the pseudo satellite dataset; and operating said one or more unmanned aerial vehicles based on the set of instructions.

In a sixth aspect, the present disclosure provides a computer-implemented method of converting a pseudo satellite dataset to an input dataset suitable for being used by a ground terminal antenna for tracking one or more unmanned aerial vehicles, the method comprising: receiving a pseudo satellite dataset of the pseudo satellite trajectory generated according to the fifth aspect, wherein the pseudo satellite dataset comprises a first epoch time associated with a first state of a pseudo satellite; converting the pseudo satellite dataset to an input dataset acceptable for the ground terminal antenna, wherein the input dataset comprises a second epoch time associated with associated with a second state of the pseudo satellite, wherein the second epoch time is at a time point before the first epoch time, wherein converting the pseudo satellite trajectory further comprising: backpropagating to the second state of the pseudo satellite with respect to the pseudo satellite trajectory, and reconstructing the input dataset based on the second state of the pseudo satellite; and uploading the input dataset to the ground terminal antenna for tracking said one or more unmanned aerial vehicles.

In a seventh aspect, the present disclosure provides a non-transitory computer-readable medium storing code for evaluating the ground terminal antenna using at least one unmanned aerial vehicle, the code comprising instructions executed by or according to any one or more aspects of a system or apparatus described herein.

It is understood that the measurements (i.e. offset and tracking) taken with respect to the ground terminal antenna are not necessarily measurements of a specific parameter. These measurements can be used when assessing the antenna performance, for example, when assessing the ability of the tracking mechanism to follow a moving target; ability of the antenna to identify a target given trajectory or other type of angular information; ability of the antenna to perform tracking in specific conditions: e.g. noisy environment, target with low or high power levels, target with trajectory errors, target is specific situations such as LEOP (launch and early acquisition), target simulating specific events (e.g. changes of frequency, of modulation type, of power levels, of throughput, etc.); ability of the antenna to track in specific angular areas; ability of the antenna to perform at a specific degree of accuracy across a specific angular area; and/or ability of a Communication On-The-Move (COTM) system to track a target whilst subject to motion either on a motion emulator or a an actual moving vehicle which can be a car, ship, airplane, train or any other relevant moving object.

Further, it is understood that the computer-implemented methods described herein may be performed by software in machine-readable form on a tangible storage medium e.g. in the form of a computer program comprising computer program code means adapted to perform all the steps of any of the methods described herein when the program is run on a base station computer/payload of the UAV where the computer program may be embodied on a computer-readable medium. Examples of tangible (or non-transitory) storage media include disks, thumb drives, memory cards etc. and do not include propagated signals. The software can be suitable for execution on a parallel processor or a serial processor such that the method steps may be carried out in any suitable order, or simultaneously.

Furthermore, the program that runs on the payload of the UAV may be adapted to operate the UAV (in real-time) to execute the orbital pass, operate the pointing mechanism directing either a mechanical stabilized gimbal with a passive antenna or an active electronical steered antenna towards the antenna under test, operate the RF system to change amplitudes, modulations, frequencies and other changes, and receive and store signal levels in the form of I/Q data, screenshots, amplitude vs. frequency plots, and the like, and execute algorithms to evaluate the received data and decide the next action.

This application acknowledges that firmware and software can be valuable, separately tradable commodities. It is intended to encompass software, which runs on or the base station computer, to carry out the desired functions. It is also intended to encompass software which “describes” or defines the configuration of the base station computer, such as HDL (hardware description language) software, as is used for designing silicon chips, or for configuring universal programmable chips, to carry out desired functions.

The optional features or options described herein may be combined as appropriate, as would be apparent to a skilled person, and may be combined with any of the aspects or embodiments of the invention.

### BRIEF DESCRIPTION OF THE DRAWINGS

Embodiments of the invention will be described, by way of example, with reference to the following drawings, in which:

FIG. 1 is a pictorial diagram illustrating a simulation of an orbiting satellite using an unmanned aerial vehicle (or pseudo satellite) in the operational environment of the ground terminal antenna in accordance with the invention;

FIG. 2 is a pictorial diagram illustrating patterns of unmanned aerial vehicle trajectories and configuration with respect to different use case in accordance with the invention;

FIG. 3 is a pictorial diagram illustrating offset (pointing) measurement of precise stationary targets and mapping the entire operational area of the ground terminal antenna in accordance with the invention;

FIG. 4 is a pictorial diagram illustrating an apparatus for simulating satellite orbital trajectory using at least one unmanned aerial vehicle configured to emulate satellite movement in accordance with the invention;

FIG. 5 is a pictorial diagram illustrating a spectrum analyzer with the system schematic in accordance with the invention;

FIG. 6 is a schematic diagram of a computer system suitable for implementing embodiments of the invention.

Common reference numerals are used throughout the figures to indicate similar features.

### DETAILED DESCRIPTION

Embodiments of the present invention are described below by way of example only. These examples represent the suitable modes of putting the invention into practice that are currently known to the Applicant although they are not the only ways in which this could be achieved. The description sets forth the functions of the example and the sequence of steps for constructing and operating the example. However, the same or equivalent functions and sequences may be accomplished by different examples.

Present invention is related to a system, apparatus, and method for evaluating satellite antennas and simulating the trajectory (and communication) of the satellite using at least one unmanned aerial vehicle (UAV). UAV typically refers to a drone but may also comprise a multirotor, a Vertical Take Off and Landing (VTOL), an unmanned helicopter, fixed wings in some instances, or any other aerial vehicle that can be controlled in 3D space. It is understood that a drone may be replaced with a UAV for any embodiments, examples, and aspects of the invention as described herein.

Present invention describes a satellite antenna measurement methodology herein described using the UAV(s). UAV(s) are configured to emulate satellite movement based on a pseudo satellite trajectory and simulate the radio frequency (RF) properties of a satellite transponder or any other radio frequency device in simplex, half-duplex, or full duplex modes, or otherwise transmitting a testing signal towards the AUT, or receiving a test signal from the AUT, or travelling in both directions in turns, or independent from each other or related to each other in any sort of locking mechanism such but not limited to one part waiting for the other before it can start functioning. The pseudo satellite trajectory may be a simulated trajectory (and communication) of the satellite in Geostationary Equatorial Orbit/Medium Earth Orbit/Low Earth Orbit, Highly Elliptical Orbit, Polar Orbit, Sun-Synchronous Orbit (GEO/MEO/LEO/HEO/PO/SSO) or any other elliptical orbit, as well as operational scenarios including but are not limited to Launch and Early Operation (LEOP), satellite deorbiting, satellite collision avoidance as described herein.

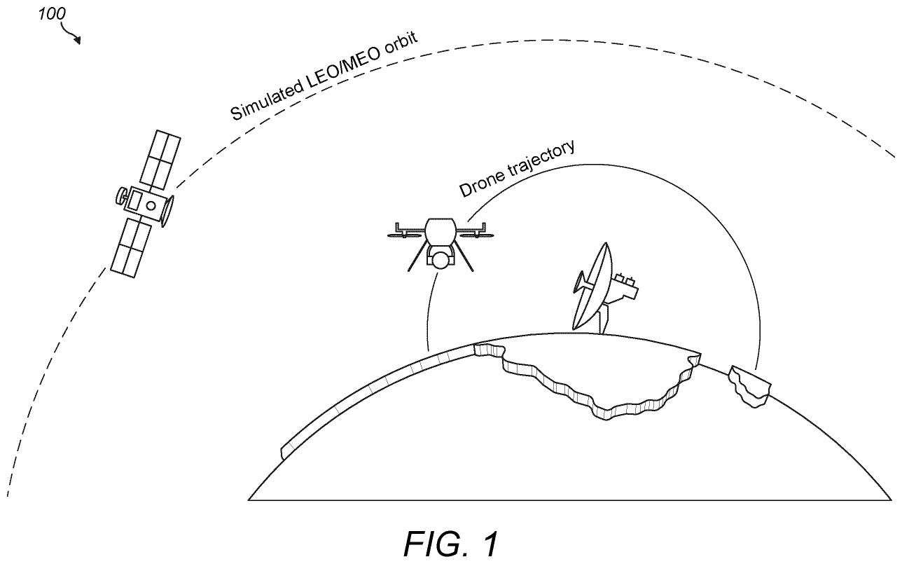

Trajectory of the satellite, or satellite trajectory, refers to the actual satellite orbital trajectory followed by the motion of a satellite around Earth. Satellite trajectory differs from pseudo satellite trajectory in that the pseudo satellite trajectory is not the actual satellite trajectory but instead a data representation of an Earth-orbiting object trajectory based on the AUT location and the operational scenario. The data representation is a projection of the satellite trajectory onto a different 3D shape/space (allowing operations using pseudo satellite(s) or UAV(s) to be conducted at altitudes and velocities lower than that of the satellite, as shown in FIG. 1).

It is understood that the pseudo satellite trajectory is not the actual trajectory of the UAV(s) used in operation, but it is projected as the target trajectory of UAV seen from the AUT on the surface in shorter range. The actual trajectory of the UAV(s) may deviate from the pseudo satellite trajectory during a scenario, resulting in errors or uncertainty. The projection of pseudo satellite trajectory can be realized as a flight path based on telemetry data and the target flight path of UAV; thus, what is being projected can be an intended/target pseudo satellite trajectory, which can be of an actual satellite or a simulated satellite. Pseudo satellite trajectory is generated based on user demand in relation to various operational scenarios without being dependent on the measurements discussed thereafter.

For example, pseudo satellite trajectory would be a representation of the intended orbital information of the satellite (existing satellite) or pseudo satellite (simulated satellite) in data formats that are typically used for storing actual or non-pseudo satellite, such as Two-Line Element (TLE) or alternatively as Earth-Centered, Earth-fixed coordinate system (ECEF), whereby the stored information comprising the trajectory or orbit of the satellites in time or with respect to a point in time.

In general, for a satellite, its TLE dataset can be generated based on the observations taken at the ground tracking stations. TLE dataset encodes the orbital parameters of the satellite. These orbital parameters include but are not limited to values for culminate (maximum) elevation, azimuth, altitude of a satellite, orbital inclination, mean anomaly, and epoch time. For example, epoch time encoded by the TLE dataset can be understood as the moment in time when the satellite's position and other orbital parameters were calculated based on observations made by the tracking stations. In other words, the TLE dataset contains information on the satellite's position for the given epoch time.

Various conventional software exists and can be used to generate the pseudo satellite trajectory based on orbital parameters defined according to an operational scenario. For example, pseudo satellite trajectory would be stored as a pseudo satellite dataset, or more specifically, as the TLE dataset as described above. Current state of the satellites can be obtained by processing the TLE dataset, while estimated future and past state of the satellite can also be obtained by “propagating” and “backpropagation” the orbital elements collected at epoch time, as described in detail in the following sections, where a state herein refers to and comprises the position and velocity of the satellite. In turn, the pseudo satellite trajectory can be used to generate the flight path of the UAV(s) based on parameters such as desired UAV distance from the AUT, allowing for the simulation of various planned scenarios.

It is assumed that pseudo satellite trajectory does not have a dependency on AUT. The trajectory is instead calculated based on the planned/operational scenario. For example, if where the AUT is installed and which satellite constellation (as part of the operational scenario) is used are known, the possible (pseudo) trajectory for testing can be generated. In other words, the pseudo satellite trajectory can be generated based on an operational scenario comprising satellite constellation information, where Operational scenarios may include but are not limited to scenarios of satellite(s) in GEO/MEO/LEO or any other elliptical orbit, as well as other operational scenarios, comprising LEOP (Launch and Early Operation), satellite deorbiting and satellite collision avoidance, as described herein.

An aspect of example apparatus/system of the present invention comprises a base station as the ground control station that keeps telemetry with the UAV(s). The telemetry herein refers to the collection of measurements and/or data, including but are not limited to localization data, instruction for UAV to generate flight path and RF measurements (measured RF data). Telemetry data may also comprise the flight sensor data from the UAV and its instruction, including but are not limited to the target state (position) of the UAV, where the target state (i.e. position, velocity and/or acceleration, including direction or the unit vector of the target position) is calculated based on the projection of pseudo satellite in the configured range. The flight sensor data may be sent to the ground station. The telemetry data from the UAV(s) may be stored at the onboard computer of the UAV(s) or at the base station. Further, the measured RF data, where RF data can be collected either by RF measurement instrument on the ground via AUT connected to the RF measurement instrument or in the air via multiple UAVs. It is understood that there may be localization uncertainty (of the position accuracy) retained in the present system and where equally applicable with respect to the AUT, such that the localization uncertainty may be reported as an uncertainty range. Due to this uncertainty, the recorded target direction as ground truth may contain error.

Base station may be (or a part of) a personal computer or computing system. Base station can be controlled by a user interface. Base station can record data, monitor, and perform flight path planning of the UAV(s). The base station establishes telemetry with UAV(s) and a ground terminal antenna, where the ground terminal antenna can be an AUT. More specifically, the base station communicates with the receiver to control the UAV(s) and collect data from the AUT. The data is analyzed and processed at the base station or on an external system or device. In addition, the computed measurement(s) of the analysis may involve assessing the throughput rate at the base station.

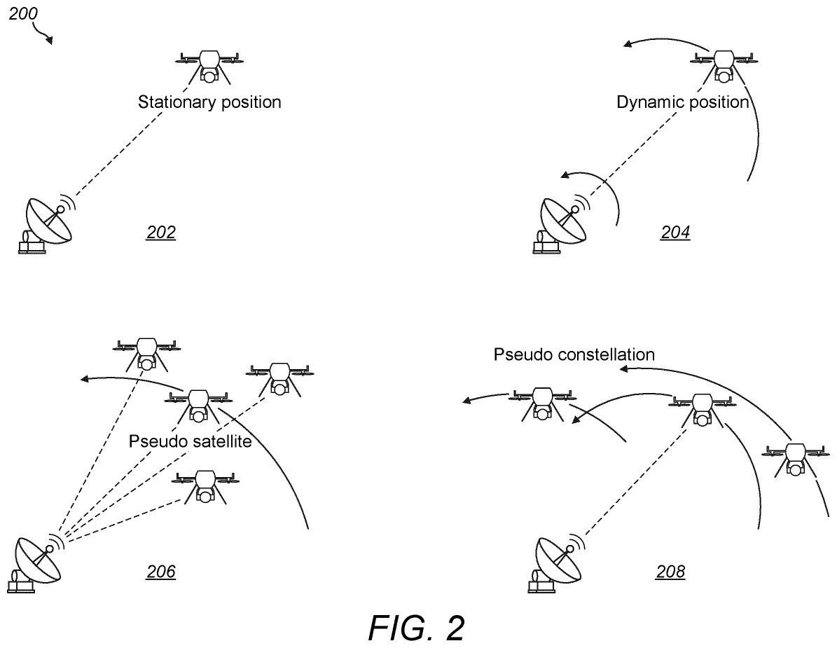

Base station may operate the UAV(s) (i.e. a drone) to fly on a flight path devised for a planned scenario involving one or more satellites. In operation, acting as pseudo satellite(s), UAV(s) can emulate said one or more satellites of the scenario. The flight path may comprise multiple paths directing the UAV(s) on different paths when emulating a scenario that involves multiple satellites or a satellite constellation. The flight path may be pre-determined and/or guided, that is when the UAV(s) is in a guided mode, to minimize the errors produced. The guided mode allows for real-time control of the UAV(s) so to ensure that the UAV(s) is always on the flight path, at the specified/expected time, and with as little deviation as possible, as further explained in relation to FIG. 2.

For example, when unguided, the UAV(s) may lag behind or need to catch up to the time-based flight path. When guided, the UAV(s) would account for the measurement taken and is feedbacked in real-time to the UAV(s) as position velocity and acceleration commands. Having a guided flight path allows the UAV(s) to stay more closely on the original flight path. A guiding mode algorithm would run in the background and compute the position velocity and/or acceleration commands to correct any deviation that the UAV(s) has made to converge towards the original flight path.

In effect, in guided mode, the guidance of the UA(s) in real-time reduces errors produced by keeping the UAV(s) as close to the target position as possible on the flight path. The guided mode allows real-time control of the UAV(s)' velocity, positions, and/or acceleration to ensure that any error resulting from UAV(s) deviating from the flight path would be minimized.

Base station is configured to process the telemetry data and perform measurement(s) while keeping telemetry between the UAV(s) and directing the UAV(s) to follow the pre-determined or guided flight path. The telemetry data is processed with respect to the pseudo satellite trajectory and target direction of UAV(s) on the flight path. While the pseudo satellite trajectory does not require additional feedback from the telemetry data, the feedback could be advantageous in reducing the error of the UAV(s) from its target flight path.

Original pseudo satellite trajectory or the emulated satellite trajectory would remain unaffected by the feedback. It is understood that the emulated satellite trajectory is determined based on one or more orbital parameters, which include but are not limited to type orbit, eccentricity, culminate (maximum) elevation and/or azimuth with respect to the AUT, time, altitude of the satellite orbital inclination, and any anomalies. Moreover, the pseudo satellite dataset underlying pseudo satellite trajectory would be converted to an input dataset acceptable to AUT for tracking the UAVs in a certain situation, as described in the later sections.

Herein scenarios or operational scenarios refer to various situations in which the AUT can potentially interact with a satellite. These scenarios include but are not limited to the case where the satellite follows the available information (e.g. TLE and ECEF-based coordinate system). In these scenarios, the satellite is misaligned with available information, or there is a discrepancy (e.g. in collision avoidance), or where limited information is known (e.g. during lunch and early operations, LEOP). Other scenarios can be with a multi-beam operation where the antenna has multiple communication beams, a scenario where the AUT is a COTM antenna, RF-related scenarios such as weather signal attenuation, various types of modulated carriers (e.g. with modulated signal, the UAV payload comprises a modem, when modulating test signal with a computational model), and application of ha ndover parameters.

In one example, the planned scenario may be a test scenario from the aspects of UAV placement. The test scenario includes 1) Multi operation: when AUT is designed to be simultaneously connected with multiple satellites, multiple UAVs following pseudo satellites'trajectories can simulate this environment; 2) Collision avoidance: there are cases where satellites urgently adjust their orbital paths to avoid the collision. It is tested if AUT can keep its communication when available trajectory information is no longer valid for this reason in this scenario; and 3) Satellite trajectory uncertainty: expected satellite position based on trajectory data contains some uncertainty. The system can emulate the uncertain environment by introducing some mismatch between the UAV flight path and expected trajectory in timing, position, and velocity,

In another example, the planned scenario may be a test scenario from the aspects of RF. The test scenario includes 1) Impairment from the environment: the signal can be attenuated or depolarized by the influence of the environment, including but not limited to, for example, rain, fog, ice, and cloud, more specifically, sandstorms, scintillation, faraday rotation, atmospheric gases, multipath contributions. This scenario can be simulated by tuning RF payload configuration; 2) Path loss effect: the distance between the satellite and the ground terminal changes through the orbit simulation, and the amplitude will vary according to the free-space path loss equation; and 3) Doppler effect: the geometry of the ground terminal and satellites changes with the movement of the satellite, and hence it causes a variation of the Doppler effect on the frequency and sampling rate. This scenario can be simulated by tuning the RF payload configuration by modifying, but not limited to, the following parameters: clock offset, center frequency offset, and sampling rate offset.

In yet another example, a planned scenario may be when a satellite is malfunctioning and not transmitting for a specific duration of time, either due to an internal error or certain regulatory requirement, for example, to avoid the GEO belt. The satellite signal might also be subject to intentional satellite jamming from other satellites as well as airborne and ground objects, which may cause the satellite to malfunction. In such cases, multiple UAVs can be used to simulate the victim and the pirate satellites.

In yet another example, the planned scenario may be a COTM test scenario, where the AUT can be installed to establish communication on the moving vehicle as intended. In this scenario, the AUT is a COTM antenna with an extra measurement set-up (the motion emulator), that is the AUT is coupled to the motion table, and the motion table generates the angular motion to simulate the targeted vehicle (e.g. ground vehicle, ferry, airplane). It is understood that offset, tracking, and handover testing can be performed during the scenario.

In the above example, the COTM antenna may be required to perform specific cessation of emission (transmission) when the pointing (and tracking) error exceeds the defined maximum threshold, where the pointing error is associated with the ground terminal antenna and with respect to operational angle and target direction of UAVs. Testing for cessation behavior of emission may thus be included in addition to tracking as part of an evaluation of the COTM antenna. For example, one of the requirements from the authority (SOMAP), which is the requirement for performing a specific cessation of emission, may comprise cessation of emission occurring within 100 msec if the pointing error exceeds a threshold of 0.5 degree and resuming transmission when the pointing error threshold is ≤0.2 degree.

The COTM test scenario is further described in the international application PCT/EP2017/080823 with reference to DK application PA201670941, relating to tracking COTM antennas. Incorporated herein by reference, PCT/EP2017/080823 provides a system capable of testing the automatic positioning (or pointing and tracking) means of a directional antenna supported by a mobile platform.

Specifically, the disclosure as incorporated relates to the use of a UAV and a control station (base station) for testing the accuracy of the automatic positioning means of a directional antenna during a satellite signal searching and/or tracking operation. The directional antenna may be a COTM antenna capable of sensing the motion involved and compensating during the communication process/testing operation. During the process, the AUT (COTM antenna) is kept pointing toward the intended direction regardless of the motion of the platform, where AUT is attached by measuring the operational angle of AUT with respect to a pseudo satellite, i.e., a UAV as described herein, where the operational angle is based on AUT coordinates typically in azimuth and elevation angle. The measurement complexity increases when non-GEO is the targeted satellite since the target direction changes with time. Further offset, tracking, and handover testing may be performed to verify this capability.

Moreover, the UAV can be adapted for: transmitting, while navigating a flight route, a signal configured for the COTM antenna to search for and/or to track; wherein the control base station is adapted for: receiving positioning data from the automatic positioning means during a predefined test period; and receiving data, such as signal strength data, from the signal tracking antenna, about the received signal from the UAV during said predefined test period, and the payload on the UAV to receive a test signal from the AUT which can be stored and post processed.

During the COTM simulation/scenario, the AUT does not necessarily need to communicate with the UAV, though a communication (as an uplink and downlink) can be established between the AUT and the UAV to transmit information that would be available for either of the devices as part of the intended design functionality of the constellation and of the AUT, where the AUT would estimate the position of the UAV and the target direction based on the TLE data and/or received signal.

UAVs would typically serve as pseudo satellites. During the COTM scenario, however, a subset of the UAVs will not. This subset of UAVs (not serving as pseudo satellites) would be arranged to measure the state, or more specifically, the operational angle and other test parameters (i.e. a sidelobe) of the AUT to evaluate whether 1) the AUT system is compensating for the motion; 2) the AUT is keeping track toward the target direction; and 3) the AUT stops emission when pointing error exceeds specific error threshold.

An algorithm at the AUT would be present for tracking the intended satellite by combining the given satellite(s) TLE/ECEF data or data with timestamped coordinates and received signal strength and maximizing the amplitude. AUT algorithm may be conical scan tracking, monopulse tracking (via a monopulse radar system), manual/program tracking, or step tracking, where the choice of the algorithm depends on the AUT being used.

In other scenarios, the UAV can simulate communication with a satellite in/on the GEO orbit. The direction of the target satellite would nearly be fixed, in the sense that, while the GEO satellite is also moving but much less with respect to Earth, the satellite would be more or less stationary. For example, the satellite is supposed to keep its position within a +/−0.15 degree box. In contrast, in different scenarios, when AUT establishes communication with a non-GEO satellite, the direction of the target satellite would change dynamically as a function of time.

For any scenario, it is understood that measurement(s) can be taken with respect to AUT. AUT can track the pseudo satellite (UAV) based on the received signal strength. In turn, AUT can be provided pseudo information/dataset about the satellite trajectory (e.g., in the format of TLE). The AUT is adapted to measure the set of operational angles when tracking the satellite. This can be done based on the signal received at the AUT directly. For example, the angle of AUT can be measured mechanically by reading from the AUT. Typically, both TLE information and received signal strength at AUT are used for or when taking the measurement(s) (e.g. precise pointing/tracking).

The measurement(s) can also be taken with respect to RF, either on the ground at the ground control station or in the air at the UAV payload. Operating a plurality of UAVs can be done electronically, meaning it is measured by comparing the measured signal strength and pre-measured radiation pattern of the AUT, and the operation angle may be calculated by suitable algorithms such as ones using table matching, stochastic filters, and machine learning.

The measurement(s) can also be taken mechanically from the AUT by using AUT's sensor to measure the operational angle, using the reads on the AUT. For example, during handover, make-before-break testing, two or more UAVs are deployed and are used to emulate the handover process, where AUT is transferred from one UAV to another, each acting as a pseudo satellite in a typical handover procedure. Since one trajectory per UAV is dedicated when it comes to taking the measurement(s), each UAV is assigned an intended trajectory, and the handover measurement in respect of the AUT is taken or measured mechanically at the base station. Another example where measurement(s) can be taken is when the UAVs are used for testing multiple beams for antennas or systems capable of that functionality, e.g. electronically steered beams with multibeam capacity.

RF payload can be installed on the UAVs to collect and process signals. During an operation, signals from the AUT, such as signal strength, could be received at the RF payload. This and similar processes are further explained in the international application PCT/EP2021/078677 with reference to UK application GB2016495, which relates to a system including a control station and a plurality of UAVs for evaluating the performance of an AUT. For example, a transmitted signal may be associated with an operational scenario, such as during rain fade and for or based on the altitude of the UAV.

Specifically, PCT/EP2021/078677, as incorporated herein by reference, discloses an antenna evaluation system for AUT comprising a control unit/station (base station) and a plurality of aircraft in communication with the control unit, each aircraft including an RF sensor module for use in measuring RF radiation and/or testing the AUT. The method, performed by the control station/unit, comprises dynamically setting the flight paths of each of the aircraft around the AUT for collecting RF radiation measurements in relation to one or more antenna performance tests; and evaluating the antenna performance of the AUT based on the collected RF radiation measurements of the AUT in relation to the one or more antenna performance tests. The evaluation system is understood to be compatible with electronically receiving the transmitted signal from the AUT at multiple UAVs in the air. The disclosed method can be adapted to improve the accuracy of measurement(s) as described herein.

The difference between multiple UAVs and a single UAV in emulating satellite trajectory is that the measurement(s), for example AUT's operational angle, does not need to be taken or read at the AUT, which in turn may provide more accurate calculation. As the measurement(s) are independent of the AUT, these measurement(s) can potentially be provided for or taken with respect to any of the AUTs. The angle of AUT can be computed based on the measured signal strength and can thus isolate the AUT from the measurement itself. In other words, the measurement can be independent of the value read at AUT, removing any inherent inaccuracy or uncertainty.

Measurement(s) that were taken may comprise an offset measurement and tracking accuracy measurement as well as any key performance indicator relevant to the operation of the AUT, modem or of satellite constellation subsystems. The offset measurement is computed based on a set of operational angles of the AUT in relation to the target direction of a single or multiple UAV(s). The offset measurement(s) is deemed an independent measurement to validate whether AUT can point toward the direction based on the received signal.

Tracking accuracy measurement may be computed based on the set of operational angles of the AUT and target angles (or angular position of the UAV), which is realized by the UAV that follows the flight path to simulate the pseudo satellite trajectory. The tracking accuracy involves the target direction to point, which changes as a function of time.

Moreover, measurement(s) may be taken for the flight path of a single or multiple UAV(s). The pre-determined flight path can thus be a pseudo satellite trajectory generated from the users'demand or based on one or more operational scenarios described herein. Based on the measurement(s), the system evaluates the pointing offset and tracking accuracy of the AUT, offering flexibly customizable scenarios using UAV(s), each with a payload (modem or signal generator and antenna).

UAV can carry a payload. The UAV is configured to carry the payload to the desired position, where sensor data are collected and sent to the base station to be evaluated. The payload may be coupled to the UAV with a gimbal system that is specifically designed to have 3 degrees of freedom (yaw, pitch, roll), for example, so that the probe antenna's boresight and polarization plane are adjusted toward the intended direction all the time. Since the polarization plane affects the measurement(s), it would be necessary to keep this plane depending on the polarization exhibited as the behaviour of the satellite antenna. In another example, the payload may also be a 2-axis gimbal, for cases when the polarization is circular, or 1-axis gimbal or any other combination between angular control on the part of a gimbal subsystem and the UAV itself. In another example, the RF signal pointing is done with the aid of an electronically steered antenna (ESA) or a plurality of ESAs. Both the mechanical gimbal pointing and the electronical pointing through the ESA are configured to stay on target, which can be the AUT position or any other relevant target for the measurement/test, using the orientation and position information from the UAV and/or the AUT and/or other elements of the testing system.

The payload on the UAV can be an RF payload. RF payload includes a portable modem (e.g. software defined radio) or/and signal generator, amplifier, and antenna. RF payload plays the role of transmitter and/or the receiver is capable of acting in simplex, half-duplex, or full duplex modes. Herein RF payload may thus refer to the load carried by the UAV in addition to its essential operational components. Having an RF payload installed on the UAV allows for receiving and/or transmitting at the payload. This is advantageous because the system can evaluate AUT communicating in two directions (Up/Downlink). Also, the system can monitor signal on the same frequency simultaneously at different locations when multiple UAVs are assigned.

Base station may be coupled with a local positioning system that is configured to obtain the target state and current state of at least one UAV, where the target direction is calculated while the current state is measured. For example, the local positioning system may provide the current state of UAV. Based on this information, the target state is further calculated by comparing the target state defined by the pseudo trajectory.

Local positioning system functions to aid the measurement of the current state for calculating the target state. For example, the local positioning system can be any GNSS-based system, or Real-time Kinematic-Global Positioning System (RTK-GPS) or a system that applies laser and theodolite, or any other system that can help establish a local positioning reference frame.

When performing the measurement, local positioning system may nevertheless introduce uncertainty to the data collected with respect to the UAV states. The data received from the local positioning system would thus comprise error(s), which is referred to as localization uncertainty. Localization uncertainty can be maintained as a range of measurement or inaccuracy, which persists as part of the evaluation and is processed at the base station.

At the base station, besides the localization uncertainty, “the path following error” is another parameter which can be used to improve the measurement accuracy. It is based on the positioning measurement system and be calculated and used in post processing or used real-time.

Base station may be further coupled to a receiving system comprising a measurement component. The measurement component may be a spectrum analyzer and/or power meter, or a computer software able to output the signal level or other signal information from the AUT, such as I/Q data, and provide it to the base station for further analysis. The receiving system is configured to collect a signal at the AUT or from UAV(s), where RF payload is installed. For example, the base station can effectively control the receiving system and collect the received signal strength at AUT (i.e. at the measurement instrument connected to AUT) or UAV(s).

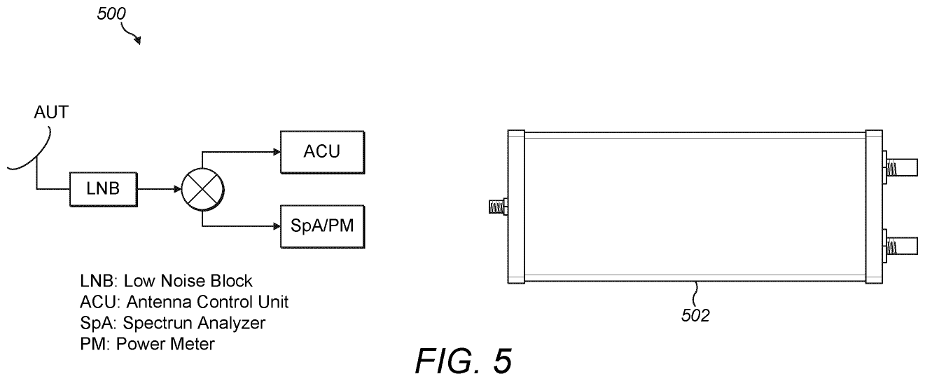

The signal is received at AUT and goes through the requisite path(s). By connecting receiving device at the end of this/these path(s), the device can make/take the measurement(s). The device may be a measurement instrument connected to AUT. For example, shown in FIG. 5, the AUT can be connected to a low noise block. The signal is passed from the AUT through the low noise block to an RF coupler. From the RF coupler, the signal is split into two paths, where the receiving system sits at one end. The signal arrives at an antenna control unit, which is part of the AUT and is separate from the base station. The base station, whereby controls the receiving system, which includes a measurement component, where the component module may be a spectrum analyzer and/or power meter, is part of the testing equipment together with the UAV(s). The base station thus does not control the AUT. For example, the base station is configured to establish a connection and communicate with AUT to automate the test sequence (e.g., providing TLE data, initiating operation, monitoring, and data collection) only. In other cases, the AUT can provide such information in data format or through an SW format by means of an Application Program Interface (API) or other data transfer options.

Base station may be coupled to a ground antenna system comprising an AUT that is to be evaluated. The telemetry data received by the base station from the UAVs for the evaluation is independent of the AUT or the data collected from the AUT, meaning that the AUT is controlled by its algorithm and not based on the data collected during any particular simulated scenario operated from/by the base station.

For COTM, AUT may be situated on a surface that is adapted to motion, where the AUT is a COTM antenna mounted on a motion emulator or vehicle (part of testing equipment/system) with the purpose of seeing whether the AUT can still track the intended satellite, albeit the unwanted motion that is emulated. AUT may read the motion of the platform where it is installed, and it is controlled by its own algorithm in order to compensate for any discrepancy. Motion emulator (alternatively less preferred approach would be to use an actual vehicle) is configured to emulate the surface motion of the AUT. The state of AUT (operational angle) is measured mechanically or electronically as described herein. As a pseudo satellite, UAV plays the role of a transmitter in respect of the base station.

UAV(s) is configured to simulate the satellite trajectory, constellation, communication, and enabled measurement(s) of the AUT for the planned scenarios and trajectory. UAV(s) can be operated and monitored by/at the base station, by the payload or by other UAV(s)/systems in a master-slave mode. The RF data collected from the UAV(s) during operation does not affect the flight path since the UAV(s) follows a set flight trajectory that is previously planned based on one or more operational scenarios.

Measurement(s) can be taken with respect to the AUT. Base station is configured to evaluate the offset and tracking accuracy in relation to the UAV(s) and takes the measurement(s), which includes but are not limited to an offset measurement based on a set of operational angles of the ground terminal antenna in relation to the target direction of said at least one UAV, or more specifically the target angle where said at least one UAV is located in direction as pseudo target satellite, and a tracking accuracy measurement based on the set of operational angles of the ground terminal antenna and target direction of said at least one unmanned aerial vehicle following the flight path for a time period, or more specifically the set of operational angles of the ground terminal antenna and the target angle where the UAV, following the flight path for a time period, is located in that direction as pseudo target satellite.

For example, the offset measurement can provide an evaluation of the pointing offset of AUT with a single UAV. The single UAV is kept hovering in a target position. Turning the tracking function to “ON” at AUT, it searches for the intended satellite by its own algorithm. Once the AUT locks on the signal, the angles of AUT and the UAV position are recorded, and angular offset values are calculated either mechanically or electronically as described herein. Offset is evaluated around the entire operational angle of AUT. The UAV hovers for a certain period at each point, and the offsets of AUT at different angles are measured.

The offset can be measured based on the relative position of the aperture of the payload with respect to the AUT to provide the target angle/angular position of the UAV(s). The offset measurement is taken when the target position is fixed or stationary (e.g. during GEO scenario) and calculated by comparing the required angle and the measured angle at AUT. Collective angular offset against the target direction of UAV(s) can be computed. This data may be post-processed on demand or in real-time.

In tracking accuracy measurement, for example, a single UAV flies by following the pseudo satellite trajectory when AUT is in tracking mode. The tracking performance of AUT is evaluated by recording the current position of the AUT in relation to the target position of the UAV or where the UAV should be. The record (current) position is compared to the AUT's output angle in every scenario where the AUT is in tracking mode.

When AUT is in the tracking mode, tracking measurement can be performed for the time period in which the target direction of the UAV is moving according to an operational scenario (e.g. during non-GEO scenario/COTM). Similarly, tracking accuracy measurement can be taken for specific trajectories, such as communication on Launch and Early Orbit phase (LEOP) trajectory, which can be a critical mission phase of satellites between separation from the launch vehicle and placement in the final orbits. These trajectories are emulated and represented by the flight path of the UAV, and the required trajectory information (e.g. TLE) is shared with the AUT.

Further, the base station may be configured to operate multiple UAVs to evaluate the offset and tracking accuracy of the AUT in relation to each of the UAV(s). In this configuration, one UAV is placed at a pseudo satellite position, and other UAVs in the formation (and the one working as a pseudo satellite) are used to collect signal strength at each position or transmit signal from each position on different frequencies. By recording the signal strength of them at AUT or of AUT at each position, the AUT's angle can be calculated with an onboard computer and/or ground station system, for example, which has been described in the international application PCT/EP2021/072560 with reference to UK application GB2012756.9, relating to gimbal stabilisation system as the ground station of an aircraft such as a UAV for use in testing AUT and applications thereof.

Specifically, PCT/EP2021/072560 discloses a gimbal structure to ensure a payload coupled to the gimbal structure when mounted on an aircraft, such as, without limitation, for example, a UAV is pointed and/or aligned with an AUT. The payload may be configured and operable to be used during an antenna performance evaluation (APE) for testing and/or measuring the performance of the AUT. The pointing and/or alignment of the payload is calculated and adjusted based on received position information such as, without limitation, for example the position/location(s), attitude, heading, and/or speed of the aircraft/gimbal structure and received position information such as, without limitation for example the position/location(s) of the AUT. From this, adjustments to the gimbal structure are made to adjust/maintain/control the pointing and/or alignment of the payload in the direction of the AUT. For example, for adjusting/controlling and/or maintaining pointing and alignment of a first section of the payload towards the AUT at least during the APE whilst the aircraft is in-flight. Adjusting the payload in this manner ensures an accurate APE test can be performed with the AUT.

The difference between the measurement, in particular tracking and offset, with a single UAV is that when using multiple UAVs, the system calculates the angle of AUT based on the measured signal strength at the system, as explained herein, thus isolating the AUT from the measurement itself. Operation method with a single UAV requires the read value at AUT. In contrast, multiple UAVs do not require the read value at AUT since the value can be calculated based on received signal strength.

Moreover, handover measurement can be taken when testing the AUT to see whether handover between satellites can be executed as intended. This can be simulated using multiple UAVs. The UAVs can be assigned to generate the intended constellations on non-GEO and/or GEO orbit for the desired period. Execution occurs when the communication of AUT is transferred to another or a different UAV from the original. Upon completion, the measurement is obtained with respect to the telemetry data collected at the base station from the UAVs. Depending on how and where the measurement data is to be stored, either real-time processing or post-processing of the UAVs' positional data, UAVs' target direction, and the read value of the operational angle of the AUT may be performed at the base station.

When connecting the satellites, during the handover test for example, the connection can be established based on one or more criteria, such as maximum distance, visibility time, capacity, visibility time subject to capacity availability, evaluation angle, and visibility time with early channel release. These criteria are weighted depending on the algorithm used by a typical satellite system.

Some of the criteria used to establish the connection do not require any communication, and orbital data can be enough. If the modem is mounted on the UAVs, the handover scenario can be extended by including the information related to the criteria in the modulated signal. The options for mounting can be 1) Modem+amplifier & antenna and 2) CW signal generator+amplifier & antenna. The 1) or former option enables the evaluation system to deal with modulated signals. This is a more advanced and complex measurement.

Further, pseudo satellite communication tests, such as protocol tests or throughput test, is also feasible, using a modem on AUT and/or payload, as planned scenario(s) herein described. It is understood that each planned scenario may be independent of another such that the base station can be used to operate the UAV(s) according to a pseudo satellite trajectory.

It is understood that a single UAV or multiple UAVs and use thereof by the present apparatus/system is directed by the base station to emulate the pseudo satellite trajectory based on a planned or operational scenario as herein described would provide a set of measurements based on signal data as required (e.g., signal strength, operational angle of AUT, throughput, throughput rate). The set of measurements calculated or determined therefrom may be used to produce and provide an evaluation of the AUT, for example. That is, the base station can be configured to produce an evaluation of the ground terminal antenna based on the set of measurements. The set of measurements and the underlying evaluation can also be used to fine-tune the parameters of the AUT, assessing any bias associated with respect to the signal data. Moreover, it would enable evaluation of each operational scenario, for example whether the handover testing is working or not, thus allowing any repair/changes of the AUT algorithm to be taken as appropriate. Some benefits of the present apparatus/system may be that the evaluation of the AUT can be accomplished anytime and under any environment, given the UAVs-based simulation.

Moreover, the attained evaluation can be used to assess the AUT, for example, by identifying physical/mechanical issues with the AUT. The evaluation can also be used downstream to improve and validate the performance of any stages of antenna (lab, development production, repairment, quality check of antenna in an operation on-site, getting approval, qualification, site acceptance testing, factory acceptance testing, calibration, troubleshooting). Provided that there are several recommendations and/or requirements stated by authorities such as ITU, FCC, SOMAP, making the evaluation procedure described herein more efficient and accessible is very important. The present invention secures the RF environment given the background where more and more communications are being used in the world.

FIG. 1 is a pictorial diagram illustrating a simulation 100 of an orbiting satellite using a UAV in the operational environment of the AUT. In the simulation, the UAV is on a flight path (or trajectory) between the pseudo satellite (that is imaginary) orbiting the Earth and with respect to the AUT. The trajectory corresponds to the orbit that is being simulated. UAV is in the direction of the pseudo satellite with respect to the AUT shown in the figure.

AUT can be measured after the installation of the testing equipment and using UAV(s) in the operational environment, as shown in the figure. When measuring AUT, mechanical or electronical measurements are possible and allow the present ground terminal system to deliver the real performance of the antenna based on one or more planned scenarios. UAVs enable tests such as the emulation of satellites for tracking and pointing measurements to be taken with respect to the AUT. These measurements may be used for assessing the AUT with respect to a particular planned/operational scenario.

For example, the measurements are adapted to enable a user, via an interface of the base station, to assess, by the base station, the performance and robustness of how the ground terminal antenna lock on a target object (i.e. a satellite) with a specific modulation, follow a moving target with a tracking mechanism, identify a target given trajectory or angular information, track under one or more specific conditions; track in one or more angular areas, achieve performance at a degree of accuracy across an angular area; and/or track a moving target, wherein the ground terminal antenna is a Communication On-The-Move antenna.

As shown in the figure, the UAVs are transmitting/receiving a test signal. The simulation is enabled by tracking orbital passes within the AUT's reference frame. Any Earth-orbiting object's specific orbital characteristics can be described with different types of positional data. One example of this data is TLE data, which encodes the motion of the orbiting object in time. The TLE data can be used by ground terminal systems to determine the pointing direction toward that object. The onboard computer at the UAV and the base station can be used to encode and decode TLE, resulting in the system knowing where to position itself to replicate the angles of view towards the reference. The data may be in ECEF or other comparable data types in replacement of TLE. The payload on the UAV acts as a satellite transponder, transmitting a test signal that the AUT can lock itself onto.

Virtual passes from any direction and at any elevation angles are generated with an algorithm in the payload or at the base station. The payload always points towards the AUT and is capable of simulating Doppler shifts, as well as signal variations due to path loss or atmospheric attenuation. Other scenarios, such as rain fade or LEOP of a satellite, can also be simulated.

The distance between each UAV and the AUT can be adjusted to any desirable value, with the limitation being the regulatory requirements of flight height and speed of the multirotor, which can reach a maximum of 20 m/s, for example. By replicating TLE orbits and matching the UAVs' speed and power, a satellite pass is emulated, and the performance of the system at tracking the UAV(s) is assessed. When using multiple UAVs, handover between satellites following different orbits can also be emulated, which enables the emulation of the passes of new satellite constellations prior to their launch.

Moreover, UAVs provide extended flexibility. For example, the flexibility introduces several diagnostic capabilities for large antennas in their outdoor operation environment, acting as, essentially, programmable, and unconstrained mechanical positioners. On the one hand, UAVs enable side lobe analysis and reflectivity diagnostics of the measurement site. Side lobe analysis are especially valuable for large, multiple-reflector dishes used in the ground segment, since subreflector misalignment can be detected this way and, subsequently, corrected and validated, thus preventing link issues due to, e.g., satellites being tracked with a side lobe. On the other hand, reflectivity diagnostics provided by the system help detect inherent problems with an antenna site, and satellite emulation allows the assessment of the tracking performance of ground station systems flexibly, with the retrieval of offset-correction data and with no need to wait for satellite passes, going as far as enabling the testing of handovers by using multiple UAVs.

As such, the usage of UAV(s) as part of the testing or testing equipment to evaluate the AUT under a simulated environment, where the UAV(s) is(are) flown on the trajectory with respect to an intended or target satellite(s), as shown in the figure, may be achieved by analyzing telemetry data and performing a set of measurements. Measurements comprise an offset measurement based on a set of operational angles of the ground terminal antenna in relation to the target direction of said at least one unmanned aerial vehicle, and a tracking accuracy measurement based on the set of operational angles of the ground terminal antenna and target direction of said at least one unmanned aerial vehicle following the flight path for a time period.

The offset measurement considers the data collected from one or more UAVs and calculates the angular offset (that is, the offset from the operational angle of the AUT by the target angle) for the AUT corresponding to the intended target satellite, where the calculation is dependent on the set of operational angles of the AUT.

Specifically, the offset measurement may comprise angle measures offset with respect to the set of operational angles of the AUT. At the AUT, the set of target angles is determined based on a pseudo satellite dataset and with respect to an aperture position of the UAV's RF payload. For example, the AUT decides where to point (or the target angle) by taking the pseudo satellite dataset (i.e. in TLE format) and the measured signal strength. AUT may calculate the set of target angles based on the pseudo satellite dataset, and the operational angle thus is realized based on this target (or set of target angles). As part of the angular position of the UAV, the aperture position to be used as a true value of target direction in the measurement may be measured at the UAV using encoders or inertial measurement units with measured state of UAV for the offset measurement.

Measurements also comprise performing a tracking accuracy measurement with respect to the AUT using said one or more UAVs based on the trajectory of each UAV projecting an orbital trajectory of a satellite, wherein tracking accuracy measurement evaluates whether the ground terminal antenna can track the target satellite with time.

It is understood that both the offset measurement and the tracking accuracy measurement can be performed with respect to the AUT. It is further understood that a handover test can be performed together with the offset and tracking accuracy measurement to determine whether an intended satellite handover is executed between satellites emulated using at least two UAVs assigned to generate an intended satellite constellation for a time period.

FIG. 2 is a pictorial diagram illustrating patterns of UAV, for example a drone, trajector(ies) and configuration(s) 200 with respect to different use cases. Patterns of the UAV trajector(ies) and configuration(s) are shown in the figure by the following items.

Item 202 is a planned use case with a single UAV, where the single UAV is at a stationary trajectory pointing in the direction of the pseudo GEO satellite and providing the simulation as such.

Item 204 is another use case with a single UAV, where the UAV is flying along a dynamic trajectory by following the direction of either a pseudo MEO/LEO or LEOP satellite and providing the simulation as such.

Item 206 is yet another use case with multiple UAVs (each equipped with a payload), where each UAV is either a stationary or a dynamic trajectory by following GEO/non-GEO satellite direction and providing the simulation as such.

Specifically, the UAV at the center of the figure is shown to simulate the pseudo satellite trajectory based on a particular operational scenario. In the scenario, multiple UAVs are deployed alongside the center UAV as subset of UAV. The base station (not shown) is configured to collect and considers the measured data from these UAVs, namely the UAV at the center, to enable electronic and numeric offset/tracking measurement of the AUT (indirectly) without having to mechanically read from the AUT.

Item 208 is yet another use case with multiple UAVs, where it is a dynamic trajectory by following pseudo non-GEO satellite constellation (with multiple trajectories) and providing the simulation for handover scenario as such.

In any of the above scenarios where multiple UAVs are being operated, it is understood that the set of measurements taken or calculated can be with respect to the UAVs assigned to emulate satellites and in relation to the AUT. A subset of these UAVs under operation may not function as pseudo satellites during a test but is used for transmitting signal to and/or receiving signal from the AUT such that set of measurements can be derived using the signal received at or transmitted from the AUT. Specifically, data such as signal strength can be received at the AUT or at the payload of a subset of UAVs in certain use cases. The signal strength of the received signal, for example can be used by the base station to determine the operational angle of the ground terminal antenna when performing the set of measurements.

Base station thereby operates the plurality of UAVs. Base station also keeps telemetry with these UAVs by obtaining telemetry data that comprises localization sensor data from the plurality of UAVs. Specifically, the base station is able to configure the plurality of UAVs to be assigned and arranged in a manner that emulates an intended satellite constellation fora length of time or to emulate operational scenarios and obtain the set of measurements derived using the operational angle of the AUT. Finally, the base station is configured to provide an evaluation of the ground terminal antenna based on the set of measurements.

An intended satellite constellation may be a pseudo non-GEO satellite constellation, which may be considered in the form of a pseudo satellite trajectory. It can be generated based on a required or user designated operational scenario(s) or satellite constellation(s) where two or more UAVs are involved. Pseudo satellite trajectory can be in a data format, such as TLE, for the AUT system to process based on the flight path that is representative of pseudo satellite trajectory in the required operational scenario. In other words, pseudo satellite trajectory is a data representation of the flight path of the UAVs with respect to an operational scenario.

It is understood that the pseudo satellite trajectory is used to control and navigate the UAVs. Telemetry data taken by the UAVs are transmitted, processed, and recorded at the base station. In other words, UAVs would act as pseudo satellites during a relevant operational scenario, simulating target satellites or satellites of a satellite constellation. The telemetry data received at the base station can also be from two or more UAVs on flight path(s). The flight path can be adjusted depending on whether UAVs receive further feedback in guided mode when operating under the scenario. Other scenarios may include the use of two or more UAVs, such as when AUT state is measured electronically for pointing and tracking measurement including handover testing scenario. Moreover, the formation of these UAVs, which are not emulating the satellite, can dynamically vary based on the measurement in real-time.

In accordance with the above, the base station can be equipped with a user interface that receives a user designated operational scenario that can be a COTM scenario. The base station may be coupled to an AUT. In COTM, the AUT can be situated on a surface with motion emulated by a motion emulator coupled to the base station. The base station is adapted to monitor and configure the emulation, or alternatively to the emulation, the AUT can be situated on a moving vehicle as described in the previous sections. In former scenarios, the AUT can be stationary and in a fixed position when the UAVs are performing testing on a pre-determined flight path.

Flight path may be a collection of paths from two or more UAVs; each UAV may follow a path amongst the collection and set based on the operational scenario. Nevertheless, the actual path of the UAVs may differ slightly from the target flight path due to position error and carry forward into the set of measurements. The set of measurements may comprise an offset measurement, a tracking measurement, including in a case of additional considerations such as a handover measurement and a COTM measurement.

The flight path may be time based during guided mode, i.e. the UAV should be at a specified angular position with respect to the AUT at a specific point in time as opposed to a flight path that is pre-determined.

In the guided mode, flight path may be adjusted based on the feedback (measured actual operational angle of the actual path of the UAVs) to increase the accuracy. Specifically, the base station may be used to compute the operational angle and continue to send the new commands for position, velocity, and/or acceleration to each of the UAVs in real-time as the UAVs continue to operate under the operational scenario. This may be a functionality of the payloads on some of the UAVs.

Pseudo satellite trajectory may be generated on demand at the base station. For example, encoded as a pseudo satellite dataset, pseudo satellite trajectory can be represented by satellite orbital parameters defined according to an operational scenario, providing the state of the pseudo satellite as a function of time.

To generate pseudo satellite trajectory, orbital parameters, such as peak elevation, azimuth angles, its time (also a.k.a. culminate azimuth, culminate elevation, culminate time) of the pseudo satellite, are defined based on the selected operation scenario so to as fix the pseudo satellite to its orbit.

Next, based on these parameters, the pseudo satellite dataset of the pseudo satellite can be generated. dataset may be constructed as if it was measured at the culminate moment (which is the future event at this moment since this step is done during the test planning phase). dataset would be used for UAV operation during the test and uploaded to AUT as its reference data which is required for AUT to track during the test.

However, as a system rule of AUT, there are cases where the AUT system only accepts the input dataset with the past epoch when it is uploaded. Since the generated dataset (described before from the orbital parameters defined according to the operational scenario) has the future epoch at this moment, further conversion of the generated pseudo satellite dataset to an input data suitable acceptable for the AUT may be required. The pseudo satellite dataset may be a TLE dataset and referred to herein as TLE.

Let the generated TLE, which has the future epoch time, be TLE1. Based on TLE1, the pseudo satellite state can be “backpropagated” to estimate the past state. Because the AUT's system accepts only the TLE with the past epoch time, the backpropagation may be continued till reaching acceptable moment for AUT system. Based on the backpropagated pseudo satellite state and its orbital information, new TLE, which has older epoch time, is generated (TLE2). Since TLE2 has an acceptable format for AUT, TLE2 can be uploaded when the test is executed. Note that TLE1 and TLE2 refer to the same pseudo satellite created based on the operational scenario. The difference is their epoch time when they are hypothetically observed at tracking stations (the epoch time of TLE1 occurs during the test and the epoch time of TLE2 occurs before uploading to AUT.) For example, on the base station, a component may be configured to collect parameters of the measurement such as peak azimuth and elevation angles, start/end elevation angle, specific start time, and distance characteristic of the UAV against the AUT, by encoding the flight path as a TLE dataset. Satellite orbital characteristics, such as but not limited to altitude and direction can also be specified along with the position of AUT for generating the TLE dataset at the base station. The base station can be adapted to provide the parameters (i.e. TLE, start/stop elevation, radius from the AUT and etc.) and the UAV would be controlled and guided using the pseudo satellite trajectory generated based on the operational scenario.

Further to the above example, a valid orbit of a hypothetical satellite and its trajectory would be generated with respect to an operational scenario or user designated operational scenario. The orbit/satellite trajectory reflecting a flight path for the UAV(s) is then passed onto the UAV(s) as a pseudo satellite trajectory. Based on the operational scenario and the orbit/satellite trajectory, the UAV(s) then executes the flight. TLE dataset for a satellite would be generated and passed over the AUT at a specified angle and time. TLE dataset is shared with the UAVs along with the current state of UAV to calculate the instructions on the next state of UAV or instructions itself is sent in real-time from base station, where the instructions on the state of UAV includes set of commands related to UAV's position, velocity and/or acceleration. The UAV(s) then positions itself at that requested distance in the direction of the hypothetical satellite as seen by the AUT. The flight path for the UAV(s) is generated, tracing the projection of the pseudo satellite at a defined distance by using guided mode. Guided mode is thus a feedback system to output the state vector command for the UAV(s) in real-time to enable the accurate realization of the operational scenario.

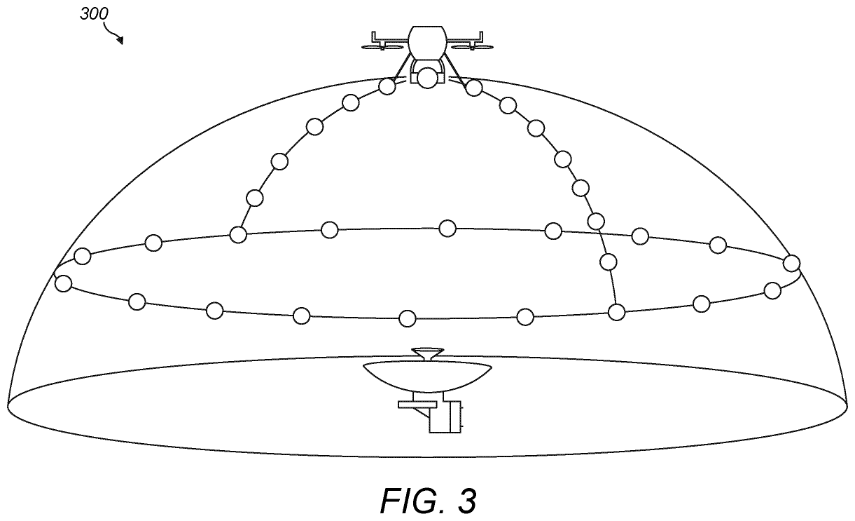

FIG. 3 is a pictorial diagram illustrating the offset (pointing) measurement of precise stationary targets and mapping 300 of the operational area or any operational angle(s) of the AUT. UAV exhibiting the operational area is shown in the figure, where the UAV flies within the operational area based on the planned scenarios. The operational area is shown around the depicted AUT as black dots surrounding the AUT.

The operational area is split into two sections. The first section is at a constant elevation, with points in azimuth stepped at, e.g. 20 degrees interval, thus isolating the performance of the azimuth axis components, and outputting the offset for that specific axis. The second section is in the elevation direction defined through a step and a start angle and stop angle. Within the operational area, the same principle of measurement can be used with a continuous flight path, similar to a trajectory.

Within this operational area or section, for example, the UAV can transmit test signals which are used by the AUT tracking system for computing the set of measurements. The UAV or multiple UAVs can also receive a signal from the AUT. The set of measurements can be taken mechanically or electronically as described herein by both the AUT and the UAVs. The set of measurements in the above example corresponds to the operational angle that is derivable using measured signal strength or RF measurements received at the base station. RF measurements may be taken by the measurement instrument connected to AUT or UAV.

Specifically, the measured signal strength or other signal characteristics and optionally the pre-measured radiation pattern of the AUT may be compared, and the operational angle of the AUT and UAV are calculated as measurements are taken. The measured results can be used to determine the pointing offset for each measured direction. The pointing offset can be averaged for the directions in which the UAV was stationary for a time period.

In a different scenario, the measured signal strength can be received from the UAV or multiple UAVs, with the AUT transmitting a test signal. This subset of UAVs comprises both a transmitter and/or a receiver for communicating with the AUT. It is understood that these UAVs are receiving the signal on the same frequency.

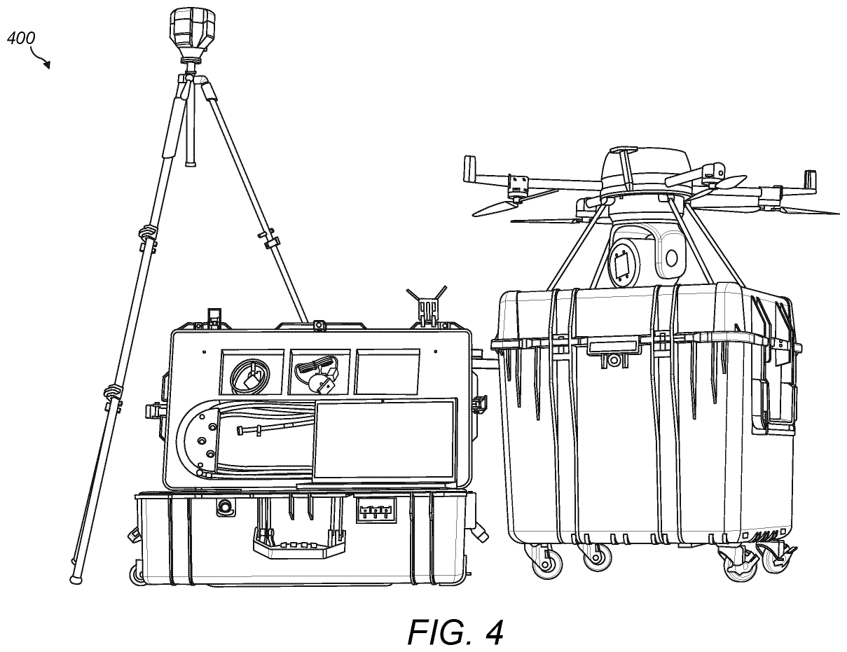

FIG. 4 is a pictorial diagram illustrating an apparatus for simulating satellite orbital trajectory 400 using at least one UAV configured to emulate satellite movement. The apparatus comprises a base station computer coupled to several other components: a local positioning system and a receiving system (shown in FIG. 5). Not shown in FIG. 4 is an AUT that will be configured to track said at least one UAV.

Specifically, UAV with the RF payload attached underneath is shown in the figure. The RF payload may include a gimbal system, for example, with three degrees of freedom or other alternatives as described herein. The black cube underneath the UAV is the transportation case for the UAV, payload, batteries, RTK station, chargers, remote, etc. On the tripod head, there is an RTK base station which provides us with centimeter level positioning accuracy. And the smaller box is the Ground Control Station, which contains a spectrum analyzer that we connect to the antenna under test, cables, tools, communication equipment both to the payload and the UAV, and the computer running our software.

In general, the base station computer is coupled to the other components for establishing telemetry with an AUT and at least one UAV on a trajectory designed for a planned/operational scenario, the base station is configured to process the telemetry data and perform one or more measurements with the described methodologies thereon, based on the operational angle and target direction of at least one UAV on the flight path, in relation to providing the orbital trajectory simulation of the satellite simulated via the UAV with respect to the planned scenario. This scenario may be a pseudo satellite trajectory emulating a satellite on an elliptical orbit, a satellite at launch, a satellite conducting operations following launch, a satellite deorbiting, a satellite situated to avoid collision with another satellite or other objects, a satellite malfunctioning and not transmitting for a while, a satellite signal passing through various atmospheric conditions, and intentional satellite jamming from other satellites as well as airborne and ground objects. The station is configured to provide an evaluation of the AUT based on the set of measurements taken with respect to the scenario.

The evaluation may be based on various metrics comprising target object (i.e. a satellite) identification; target locking; target tracking, for example, metrics such as the ability of the AUT to lock on an RF target with a specific modulation, ability of the tracking mechanism to follow a moving target, ability of the AUT to identify a target given trajectory or other types of angular information, ability of the AUT to perform tracking in specific conditions, target with low or high power levels, target with trajectory errors, target is specific situations such as LEOP, target simulating specific events, ability of the AUT to track in specific angular areas, ability of the AUT to perform at a specific degree of accuracy across a specific angular area, ability of a COTM system to track a target whilst subject to motion either on a motion emulator or a moving vehicle which can be a car, ship, airplane, train or any other relevant moving object.

Further, it is understood that the pseudo satellite trajectory is not generated based on any of the measurements but is pre-determined or guided based on a scenario as user demands. Instead, it is based on one or more orbital parameters and is representative of flight paths of the UAV(s) operating under a scenario. The trajectory can be stored on the base station as a pseudo satellite dataset representative of satellite orbital elements and applied to direct UAV(s) on flight paths associated with the scenario.

The measurements performed on telemetry data include an offset measurement based on a set of operational angles of the AUT in relation to the target direction of at least one UAV and a tracking accuracy measurement based on the set of operational angles and position of the AUT in relation to the flight path of at least one UAV. The offset measurement comprises angle measures of offset from the set of operational angles for the AUT. Base station of the apparatus is configured to evaluate the offset and tracking accuracy of the AUT in relation to the pseudo satellite based on the measurements. The tracking and offset measurements can be taken sequentially, for example, the offset measurement can be taken when the tracking tests are done.

AUT is further configured to track said at least one UAV using a pseudo satellite dataset associated with the pseudo satellite trajectory and based on signal received at AUT. When tracking said at least one UAV based on signal received at the AUT, it is understood that the set of operational angles of the AUT can be measured and collected. The measurements can be taken mechanically or electronically with respect to the set of operational angles. The measurements taken are used to assess the AUT with respect to one or more of: target identification; target locking; target tracking, target tracking in one or more angular areas; and target performance meeting a degree of accuracy across an angular area.

For example, measurements of antenna tracking and offset taken for assessing 1) ability of the AUT to lock on an RF target with a specific modulation; 2) ability of the tracking mechanism to follow a moving target; 3) ability of the AUT to identify a target given trajectory or other type of angular information; 4) ability of the AUT to perform tracking in specific conditions: e.g. noisy environment, target with low or high power levels, target with trajectory errors, target is specific situations such as LEOP (launch and early acquisition), target simulating specific events (e.g. changes of frequency, of modulation type, of power levels, of throughput, etc.); 5) ability of the AUT to track in specific angular areas; 6) ability of the AUT to perform at a specific degree of accuracy across a specific angular area; 7) ability of a COTM system to track a target whilst subject to motion either on a motion emulator or a an actual moving vehicle which can be a car, ship, airplane, train or any other relevant moving object.

The local positioning system may be used with the base station. The local positioning system can be coupled to the base station, where it is used to measure the current position of the UAV or to calculate the target direction of at least one UAV. The local positioning system is configured to collect data with respect to a state (i.e. current state, where the current state may be used to compute a target state) of said at least one UAV when operating under a particular scenario. The data received from the local positioning system would be part of the evaluation and processed at the base station, where the results are evaluated.

FIG. 5 is a pictorial diagram illustrating an example system 500 comprising a spectrum analyzer 502. The spectrum analyzer 502 may be part of a receiving instrument, system, device, or component coupled to the base station. The receiving system may comprise a measurement component, for example, a spectrum analyzer as the receiver as shown. The receiving system may be integrated with the overall base station system. The receiving system is configured to collect a signal at the AUT from at least one UAV using the measurement component. The receiving system is the end of the signal path and receives a signal transmitted from the AUT. The receiving system may be connected to the AUT to receive and process/measure its signal. The receiving system may also be on the UAV to receive signal transmitted from the AUT.

For example, the receiving device comprises the spectrum analyzer 502 and/or power meter, whereas the spectrum analyzer 502 and/or power meter is configured to receive the signal from AUT. The signal may be passed from the AUT to an RF coupler through a low noise block. The signal arrives at the receiving device (or the receiver) of the base station. In a different example not shown in FIG. 5, the receiving device may be a spectrum analyzer, power meter, software defined radio, or a combination thereof that is coupled to the UAV as it receives telemetry data.

Further to these examples, there may be an AUT and a motion emulator coupled to the AUT. Here, the motion emulator is used to test certain scenarios, i.e. a COTM scenario, where the AUT is a COTM antenna. AUT is to be evaluated at the base station. The variation of COTM antenna as the AUT depends on the planned scenario, and likewise on the algorithm used for tracking the intended satellite. The motion emulator is used to emulate surface motion where the AUT is situated. The motion emulator may be a motion table or emulator connected to the AUT during the simulation in place to emulate the motion of a moving vehicle. It is understood that the motion emulator can be implemented with respect to any of the scenarios described herein and in accordance with FIG. 2.

More specifically, the motion emulator is understood to generate the angular motion which the AUT would experience in a moving environment during COTM testing. The COTM testing is typically applied to evaluate if AUT can compensate for motion and maintain the connection to the intended satellite in motion. The motion emulator would emulate the surface motion associated with the COTM antenna situated on a moving vehicle (e.g. car, ship, airplane, train). The COTM testing can be performed using a moving vehicle as an alternative to the motion table.

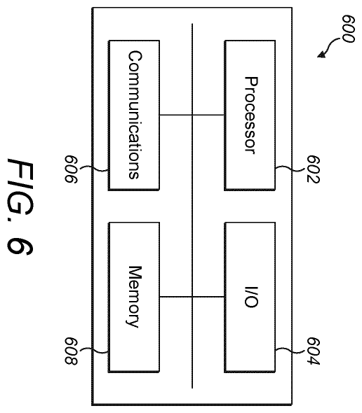

FIG. 6 is a block diagram of a base station computer or device, which includes an onboard computer, that may be used to implement or as system(s), apparatus, method(s), and/or process(es) combinations thereof, modifications thereof, and/or as described with reference to FIGS. 1 to 5 and/or as described herein. Computing apparatus/system 600 includes one or more processor unit(s) 602, an input/output unit 604, communications unit/interface 606, a memory unit 608 in which the one or more processor unit(s) 602 are connected to the input/output unit 604, communications unit/interface 606, and the memory unit 608. In some embodiments, the computing apparatus/system 600 may be a server, or one or more servers networked together. In some embodiments, the computing apparatus/system 600 may be a herein described computer or supercomputer/processing facility or hardware/software suitable for processing or performing one or more aspects of system(s), apparatus, method(s), and/or process(es) combinations thereof, modifications thereof, and/or as described with reference to FIGS. 1 to 5 and/or as described herein. The communications interface 606 may connect the computing apparatus/system 600, via a communication network, with one or more services, devices, server system(s), cloud-based platforms, systems for implementing subject-matter databases and/or knowledge graphs for implementing the invention as described herein. The memory unit 608 may store one or more program instructions, code or components such as, by way of example only but not limited to, an operating system and/or code/component(s) associated with the process(es)/method(s) as described with reference to FIGS. 1 to 5, additional data, applications, application firmware/software and/or further program instructions, code and/or components associated with implementing the functionality and/or one or more function(s) or functionality associated with one or more of the method(s) and/or process(es) of the device, service and/or server(s) hosting the process(es)/method(s)/system(s), apparatus, mechanisms and/or system(s)/platforms/architectures for implementing the invention as described herein, combinations thereof, modifications thereof, and/or as described with reference to at least one of the FIGS. 1 to 5.

In relation to FIGS. 1 to 6 and examples described therein, the skilled person would appreciate that any of the following aspects of the present disclosure may be combined or is combinable with any other aspect(s) or described example(s) unless specified otherwise.

An aspect of the present invention is an apparatus for evaluating the ground terminal antenna. The apparatus performs one or more measurements of ground terminal antenna using at least one unmanned aerial vehicle configured to emulate satellite movement based on a pseudo satellite trajectory, the apparatus comprising: a base station for establishing telemetry with a ground terminal antenna and said at least one unmanned aerial vehicle on a flight path designed for a planned scenario of a satellite, the base station is configured to process the telemetry data and perform one or more measurements thereon, based on the operational angle and target direction of said at least one unmanned aerial vehicle on the flight, in relation to providing the orbital trajectory simulation of the satellite with respect to the planned scenario; and wherein said one or more measurements comprise an offset measurement based on a set of operational angles of the ground terminal antenna in relation to the target direction of said at least one unmanned aerial vehicle; and a tracking accuracy measurement based on the set of operational angles of the ground terminal antenna and target direction of said at least one unmanned aerial vehicle following the flight path for a time period.

In another aspect is an apparatus for simulating satellite orbital trajectory using a plurality of unmanned aerial vehicles, wherein the apparatus comprising: a base station controlled by a user interface to keep telemetry with the plurality of unmanned aerial vehicles and a ground terminal antenna, the base station is configured to monitor the plurality of unmanned aerial vehicles, record and analyze the data received from the plurality of unmanned aerial vehicles, and generate flight paths emulating satellite movement based on user input of one or more operational scenarios; and wherein the analysis comprises performing a set of measurements in relation to the data received during the telemetry.

In another aspect is system, wherein the system comprising an apparatus configured according to the above aspects, and/or adapted to carry out any of the methods or methods steps described herein.

In another aspect is a method of obtaining measurements taken with respect to one or more unmanned aerial vehicles, the method comprising: performing an offset measurement using collected operational angle to determine the angular offset for a ground terminal antenna corresponding to the target direction of said one or more unmanned aerial vehicles, wherein the offset measurement is dependent on a set of operational angles of the ground terminal antenna; and performing a tracking accuracy measurement with respect to the ground terminal antenna using said one or more unmanned aerial vehicles based on the trajectory of each unmanned aerial vehicle projecting an orbital trajectory of a satellite, wherein tracking accuracy measurement

In another aspect is a method of providing a pseudo satellite dataset used for operating one or more unmanned aerial vehicles, the method comprising: designating an operational scenario; obtaining parameters associated with the operational scenario; generating the pseudo satellite dataset based on the operational scenario; generating a set of instructions associated with a state based on the pseudo satellite dataset; and sending the set of instructions for operating said one or more unmanned aerial vehicles in relation to the pseudo satellite dataset; and operating said one or more unmanned aerial vehicles based on the set of instructions.

In another aspect is a method of converting a pseudo satellite dataset to an input dataset suitable for being used by a ground terminal antenna for tracking one or more unmanned aerial vehicles, the method comprising: receiving a pseudo satellite dataset of the pseudo satellite trajectory generated according to any other method described herein, wherein the pseudo satellite dataset comprises a first epoch time associated with a first state of a pseudo satellite; converting the pseudo satellite dataset to an input dataset acceptable for the ground terminal antenna, wherein the input dataset comprises a second epoch time associated with associated with a second state of the pseudo satellite, wherein the second epoch time is at a time point before the first epoch time, wherein converting the pseudo satellite trajectory further comprising: backpropagating to the second state of the pseudo satellite with respect to the pseudo satellite trajectory, and reconstructing the input dataset based on the second state of the pseudo satellite; and transmitting the input dataset to the ground terminal antenna for tracking said one or more unmanned aerial vehicles.

In another aspect is a non-transitory computer-readable medium storing code for evaluating the ground terminal antenna using at least one unmanned aerial vehicle, the code comprising instructions executed by or according to any one or more aspects of a system or apparatus described herein.

In relation to the above aspects, the skilled person would appreciate that any of the following aspects of the present disclosure may be combined or is combinable with any of the following option(s) notwithstanding the dependency specified elsewhere.

As an option, one or more measurements are used for making an assessment of the ground terminal antenna with respect to one or more of: target identification; target locking; target tracking, target tracking in one or more angular areas; and target performance meeting a degree of accuracy across an angular area. As another option, the planned scenario comprises a satellite on an elliptical orbit, a satellite at launch, a satellite conducting operations following launch, a satellite deorbiting, a satellite situated to avoid collision, a satellite malfunctioning and not transmitting for a while, a satellite signal passing through various atmospheric conditions, and intentional satellite jamming from other satellites as well as airborne and ground objects. As another option, the base station is configured to evaluate offset and tracking accuracy of the ground terminal antenna in relation to said at least one unmanned aerial vehicle based on said one or more measurements. As another option, wherein the offset measurement comprises angle measures offset from the set of operational angles for the ground terminal antenna. As another option, the pseudo satellite trajectory is stored on the base station as a pseudo satellite dataset representative of satellite orbital elements. As another option, the pseudo satellite trajectory is applied to direct said at least one unmanned aerial vehicle on the flight path. As another option, the ground terminal antenna is configured to track said at least one unmanned aerial vehicle using a pseudo satellite dataset associated with the pseudo satellite trajectory and based on signal received at the ground terminal antenna. As another option, when tracking said at least one unmanned aerial vehicle based on signal received at the ground terminal antenna, the set of operational angles of the ground terminal antenna is measured and collected. As another option, the set of operational angles is measured mechanically with respect to the ground terminal antenna. As another option, the ground terminal antenna is configured to track said at least one unmanned aerial vehicle that changes a direction with respect to the ground terminal antenna as a function of time. As another option, the pseudo satellite trajectory is generated based on one or more orbital parameters. As another option, said at least one unmanned aerial vehicle comprises an RF payload coupled to said at least one unmanned aerial vehicle with a gimbal system with three degrees of freedom. As another option, the beam can be steered using phased array in place of the gimbal system. As another option, the telemetry is kept with said at least one unmanned aerial vehicle having an RF payload or at the base station. As another option, further comprising: a local positioning system coupled to the base station, wherein the local positioning system is configured to obtain a state of UAV of said at least one unmanned aerial vehicle. As another option, further comprising: a receiving system comprises a measurement component, wherein the receiving system is configured to collect a signal from the ground terminal antenna or at least one unmanned aerial vehicle using the measurement component. As another option, the measurement component is a spectrum analyzer, a power meter, or spectrum analyzer and a power meter. As another option, further comprising: a ground antenna system configured to be evaluated with respect to the base station, wherein the ground antenna system comprises the ground terminal antenna. As another option, further comprising: a motion emulator configured to emulate surface motion of the ground terminal antenna, wherein the ground terminal antenna is a Communication On-The-Move antenna.

As a further option, the set of measurements comprises an offset measurement and a tracking accuracy measurement, wherein the offset and tracking accuracy measurements are taken with respect to the ground terminal antenna. As a further option, the set of measurements comprises performing a handover measurement using the plurality of unmanned aerial vehicles assigned to emulate more than two satellites. As a further option, the set of measurements is determined based on operational angle of the ground terminal antenna, wherein the operational angle is derivable using measured signal strength received at the base station, wherein the measured signal strength is either transmitted from ground terminal antenna and received at the plurality of unmanned aerial vehicles on a single frequency or transmitted from the plurality of unmanned aerial vehicles and received at ground terminal antenna on multiple differentiating frequencies. As a further option, the measured signal strength comprises radio frequency measurements taken at the plurality of unmanned aerial vehicles. As a further option, the measured signal strength transmitted at multiple differentiating frequencies corresponds to a subset of unmanned aerial vehicles not functioning as pseudo satellites. As a further option, the subset of unmanned aerial vehicles comprises unmanned aerial vehicles that serve as a transmitter and/or a receiver with respect to the ground terminal antenna. As a further option, the base station operates the plurality of unmanned aerial vehicles for a time period emulating an intended satellite constellation or operational scenario and obtaining the set of measurements. As a further option, the data received comprise signal strength received at the ground terminal antenna or at payload of each unmanned aerial vehicle. As a further option, the signal strength is used by the base station to determine operational angle of the ground terminal antenna when performing the set of measurements. As a further option, the telemetry is kept with the plurality of unmanned aerial vehicles by obtaining telemetry data that comprises localization sensor data from the plurality of unmanned aerial vehicles. As a further option, the base station is adapted to configure the plurality of unmanned aerial vehicles to be assigned and arranged in a manner that produces an intended satellite constellation for a period in order to emulate multiple satellite trajectories or measure operational angle of the ground terminal antenna. As a further option, wherein the base station comprises a measurement component connected to the ground terminal antenna, wherein the measurement component is adapted to measure signal from the ground terminal antenna. As a further option, the ground terminal antenna is configured to transmit signal that is receivable at said at least one unmanned aerial vehicle with an RF payload situated on said at least one unmanned aerial vehicle. As a further option, the base station is configured to provide an evaluation of the ground terminal antenna based on the set of measurements. As a further option, further comprising: performing a handover test to determine whether an intended satellite handover is executed between satellites emulated using at least two unmanned aerial vehicles assigned to generate an intended satellite constellation for a time period. As a further option, the operational scenario comprises a satellite constellation such that at least two or more unmanned aerial vehicles are appliable for the generation of the pseudo satellite trajectory. As a further option, the ground terminal antenna is an COTM antenna situated on a surface with motion emulated by a motion emulator. As a further option, performing an evaluation of the ground terminal antenna that is a Communication On-The-Move antenna, wherein the evaluation is based on: 1) the Communication On-The-Move antenna is compensating for motion; 2) the Communication On-The-Move antenna is keeping track toward a target direction; and 3) the Communication On-The-Move antenna is able to stop emission when pointing error exceeds an error threshold.

In the embodiments, examples, and aspects of the invention as described above such as process(es), method(s), and/or system(s) and/or components may be implemented on and/or comprise one or more cloud platforms, one or more server(s) or computing system(s) or device(s). A server may comprise a single server or network of servers, the cloud platform may include a plurality of servers or network of servers. In some examples the functionality of the server and/or cloud platform may be provided by a network of servers distributed across a geographical area, such as a worldwide distributed network of servers, and a user may be connected to an appropriate one of the network of servers based upon a user location and the like.

The above description discusses embodiments of the invention with reference to a single user for clarity. It will be understood that in practice the system may be shared by a plurality of users, and possibly by a very large number of users simultaneously.

The embodiments described above may be configured to be semi-automatic and/or are configured to be fully automatic. In some examples a user or operator of the querying system(s)/process(es)/method(s) may manually instruct some steps of the process(es)/method(s) to be carried out.

The described embodiments of the invention a system, process(es), method(s) and the like according to the invention and/or as herein described may be implemented as any form of a computing and/or electronic device, for example basic computer schematic shown in FIG. 6. The invention may comprise one or more processors which may be microprocessors, controllers or any other suitable type of processors for processing computer executable instructions to control the operation of the device in order to gather and record routing information. In some examples, for example where a system on a chip architecture is used, the processors may include one or more fixed function blocks (also referred to as accelerators) which implement a part of the process/method in hardware (rather than software or firmware). Platform software comprising an operating system or any other suitable platform software may be provided at the computing-based device to enable application software to be executed on the device.

Various functions described herein can be implemented in hardware, software, or any combination thereof. If implemented in software, the functions can be stored on or transmitted over as one or more instructions or code on a computer-readable medium or non-transitory computer-readable medium. Computer-readable media may include, for example, computer-readable storage media. Computer-readable storage media may include volatile or non-volatile, removable or non-removable media implemented in any method or technology for storage of information such as computer-readable instructions, data structures, program modules or other data. A computer-readable storage media can be any available storage media that may be accessed by a computer. By way of example, and not limitation, such computer-readable storage media may comprise RAM, ROM, EEPROM, flash memory or other memory devices, CD-ROM or other optical disc storage, magnetic disc storage or other magnetic storage devices, or any other medium that can be used to carry or store desired program code in the form of instructions or data structures and that can be accessed by a computer. Disc and disk, as used herein, include compact disc (CD), laser disc, optical disc, digital versatile disc (DVD), floppy disk, and blu-ray disc (BD). Further, a propagated signal is not included within the scope of computer-readable storage media. Computer-readable media also includes communication media including any medium that facilitates transfer of a computer program from one place to another. A connection or coupling, for instance, can be a communication medium. For example, if the software is transmitted from a website, server, or other remote source using a coaxial cable, fiber optic cable, twisted pair, DSL, or wireless technologies such as infrared, radio, and microwave are included in the definition of communication medium. Combinations of the above should also be included within the scope of computer-readable media.

Alternatively, or in addition, the functionality described herein can be performed, at least in part, by one or more hardware logic components. For example, and without limitation, hardware logic components that can be used may include Field-programmable Gate Arrays (FPGAs), Program-specific Integrated Circuits (ASICs), Program-specific Standard Products (ASSPs), System-on-a-chip systems (SOCs). Complex Programmable Logic Devices (CPLDs), etc.

Although illustrated as a single system, it is to be understood that the computing device may be a distributed system. Thus, for instance, several devices may be in communication by way of a network connection and may collectively perform tasks described as being performed by the computing device.

Although illustrated as a local device it will be appreciated that the computing device may be located remotely and accessed via a network or other communication link (for example using a communication interface).

The term ‘computer’ is used herein to refer to any device with processing capability such that it can execute instructions. Those skilled in the art will realise that such processing capabilities are incorporated into many different devices and therefore the term ‘computer’ includes PCs, servers, IoT devices, mobile telephones, personal digital assistants and many other devices.

Those skilled in the art will realise that storage devices utilised to store program instructions can be distributed across a network. For example, a remote computer may store an example of the process described as software. A local or terminal computer may access the remote computer and download a part or all of the software to run the program. Alternatively, the local computer may download pieces of the software as needed, or execute some software instructions at the local terminal and some at the remote computer (or computer network). Those skilled in the art will also realise that by utilising conventional techniques known to those skilled in the art that all, or a portion of the software instructions may be carried out by a dedicated circuit, such as a DSP, programmable logic array, or the like.

It will be understood that the benefits and advantages described above may relate to one embodiment or may relate to several embodiments. The embodiments are not limited to those that solve any or all of the stated problems or those that have any or all of the stated benefits and advantages. Variants should be considered to be included into the scope of the invention.

Any reference to ‘an’ item refers to one or more of those items. The term ‘comprising’ is used herein to mean including the method steps or elements identified, but that such steps or elements do not comprise an exclusive list and a method or apparatus may contain additional steps or elements.

As used herein, the terms “component” and “system” are intended to encompass computer-readable data storage that is configured with computer-executable instructions that cause certain functionality to be performed when executed by a processor. The computer-executable instructions may include a routine, a function, or the like. It is also to be understood that a component or system may be localized on a single device or distributed across several devices. Further, as used herein, the term “exemplary”, “example” or “embodiment” is intended to mean “serving as an illustration or example of something”. Further, to the extent that the term “includes” is used in either the detailed description or the claims, such term is intended to be inclusive in a manner similar to the term “comprising” as “comprising” is interpreted when employed as a transitional word in a claim.

The figures illustrate exemplary methods. While the methods are shown and described as being a series of acts that are performed in a particular sequence, it is to be understood and appreciated that the methods are not limited by the order of the sequence. For example, some acts can occur in a different order than what is described herein. In addition, an act can occur concurrently with another act. Further, in some instances, not all acts may be required to implement a method described herein.

Moreover, the acts described herein may comprise computer-executable instructions that can be implemented by one or more processors and/or stored on a computer-readable medium or media. The computer-executable instructions can include routines, sub-routines, programs, threads of execution, and/or the like. Still further, results of acts of the methods can be stored in a computer-readable medium, displayed on a display device, and/or the like.

The order of the steps of the methods described herein is exemplary, but the steps may be carried out in any suitable order, or simultaneously where appropriate. Additionally, steps may be added or substituted in, or individual steps may be deleted from any of the methods without departing from the scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art.

What has been described above includes examples of one or more embodiments. It is, of course, not possible to describe every conceivable modification and alteration of the above devices or methods for purposes of describing the aforementioned aspects, but one of ordinary skill in the art can recognize that many further modifications and permutations of various aspects are possible. Accordingly, the described aspects are intended to embrace all such alterations, modifications, and variations that fall within the scope of the appended claims.

1. An apparatus for performing one or more measurements of ground terminal antenna using at least one unmanned aerial vehicle configured to emulate satellite movement based on a pseudo satellite trajectory, the apparatus comprising:
a base station for establishing telemetry with a ground terminal antenna and said at least one unmanned aerial vehicle on a flight path designed for a planned scenario of a satellite, the base station is configured to process the telemetry data and perform one or more measurements thereon, based on a set of operational angles and target direction of said at least one unmanned aerial vehicle on the flight path, in relation to providing satellite orbital trajectory simulation with respect to the planned scenario; and
wherein said one or more measurements comprise 1) an offset measurement based on the set of operational angles of the ground terminal antenna in relation to the target direction of said at least one unmanned aerial vehicle; and 2) a tracking accuracy measurement based on the set of operational angles of the ground terminal antenna and target direction of said at least one unmanned aerial vehicle following the flight path for a time period.

2. The apparatus of claim 1, wherein said one or more measurements are used for making an assessment of the ground terminal antenna with respect to one or more of: target identification, target locking, target tracking, target tracking in one or more angular areas, and target performance meeting a degree of accuracy across an angular area.

3. The apparatus of claim 1, wherein the planned scenario comprises a satellite on an elliptical orbit, a satellite at launch, a satellite conducting operations following launch, a satellite deorbiting, a satellite situated to avoid collision, a satellite malfunctioning and not transmitting, a satellite signal traversing various atmospheric conditions, and a scenario of intentional satellite jamming.

4. The apparatus of claim 1, wherein the base station is configured to evaluate offset and tracking accuracy of the ground terminal antenna in relation to said at least one unmanned aerial vehicle based on said one or more measurements.

5. The apparatus of claim 1, wherein the offset measurement comprises angle measures offset from the set of operational angles for the ground terminal antenna.

6. The apparatus of claim 1, wherein the pseudo satellite trajectory is stored on the base station as a pseudo satellite dataset representative of satellite orbital elements.

7. The apparatus of claim 1, wherein the pseudo satellite trajectory is applied to direct said at least one unmanned aerial vehicle on the flight path.

8. The apparatus of claim 1, wherein the ground terminal antenna is configured to track said at least one unmanned aerial vehicle using a pseudo satellite dataset of the pseudo satellite trajectory and based on signal received at the ground terminal antenna.

9. The apparatus of claim 1, when tracking said at least one unmanned aerial vehicle based on signal received at the ground terminal antenna, the set of operational angles of the ground terminal antenna is measured and collected.

10. The apparatus of claim 1, wherein the set of operational angles is measured mechanically with respect to the ground terminal antenna.

11. The apparatus of claim 1, further comprising: performing an evaluation of the ground terminal antenna that is a Communication On-The-Move antenna, wherein the evaluation is based on: 1) the Communication On-The-Move antenna is compensating for motion; 2) the Communication On-The-Move antenna is keeping track toward a target direction; and 3) the Communication On-The-Move antenna is able to stop emission when pointing error exceeds an error threshold.

12. The apparatus of claim 1, wherein the ground terminal antenna is configured to track said at least one unmanned aerial vehicle that changes a direction with respect to the ground terminal antenna as a function of time, and, wherein the pseudo satellite trajectory is generated based on one or more orbital parameters.

13. (canceled)

14. The apparatus of claim 1, wherein said at least one unmanned aerial vehicle comprises a radio frequency payload coupled to said at least one unmanned aerial vehicle with a mechanical or electrical pointing mechanism.

15. The apparatus of claim 1, wherein the flight path is a guided flight path that enables real-time control of said at least one unmanned aerial vehicle through the base station.

16. The apparatus of claim 1, further comprising:
a local positioning system coupled to the base station, wherein the local positioning system is configured to obtain the a state of said at least one unmanned aerial vehicle; and
a receiving system comprises a measurement component, wherein the receiving system is configured to process a signal from the ground terminal antenna or at least one unmanned aerial vehicle using the measurement component.

17. (canceled)

18. The apparatus of claim 1, wherein the measurement component is a spectrum analyzer, a power meter, an SDR, one or more signal measurement devices, or a combination thereof.

19. The apparatus of claim 1, further comprising: a motion emulator configured to emulate surface motion of the ground terminal antenna, wherein the ground terminal antenna is a Communication On-The-Move antenna;
or wherein the ground terminal antenna is a Communication On-The-Move antenna situated on a moving vehicle.

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. A computer-implemented method of obtaining measurements taken with respect to one or more unmanned aerial vehicles, the method comprising:
performing an offset measurement using data collected from said one or more unmanned aerial vehicles to determine the angular offset for a ground terminal antenna corresponding to the target direction of said one or more unmanned aerial vehicles, wherein the offset measurement is dependent on a set of operational angles of the ground terminal antenna; and/or
performing a tracking accuracy measurement with respect to the ground terminal antenna using said one or more unmanned aerial vehicles based on the trajectory of each unmanned aerial vehicle projecting an orbital trajectory of a satellite, wherein tracking accuracy measurement evaluates whether the ground terminal antenna can track the target satellite with time.

38. The method of claim 37, further comprising:
performing a handover test to determine whether an intended satellite handover is executed between satellites emulated using at least two unmanned aerial vehicles assigned to generate an intended satellite constellation for a time period.

39. The method of claim 37, wherein the method is performed by the apparatus configured according to claim 1.

40. (canceled)

41. (canceled)

42. (canceled)

43. (canceled)

44. (canceled)

45. (canceled)
